(19) United States
(12) Patent Application Publication
(10) Pub. No.: US 2007/0126437 A1
(43) Pub. Date: Jun. 7, 2007

(54) Printed circuit board and inspected unit

(75) Inventor: Jae-chun Sul, Suwon-si (KR)

Correspondence Address: STANZIONE & KIM, LLP, 919 18TH STREET, N.W., SUITE 440, WASHINGTON, DC, 20006, US

(73) Assignee: SAMSUNG Electronics Co., Ltd., Suwon-si (KR)

(21) Appl. No.: 11/493,802

(22) Filed: Jul. 27, 2006

(30) Foreign Application Priority Data
Nov. 24, 2005 (KR) 2005-113157

(51) Int. Cl. G01R 31/02

(52) U.S. Cl. 324/754

(57) ABSTRACT

A printed circuit board includes a substrate and an inspection piece part having a solder part provided on a surface of the substrate to be inspected by an inspecting apparatus. Thus, the printed circuit board and an inspected unit can efficiently be inspected without being disassembled and damaged.

### CROSS-REFERENCE TO RELATED APPLICATIONS

This application claims priority from Korean Patent Application No. 2005-0113157, filed on Nov. 24, 2005, in the Korean Intellectual Property Office, the disclosure of which is incorporated herein by reference.

### BACKGROUND OF THE INVENTION

1. Field of the Invention

The present general inventive concept relates to a printed circuit board and an inspected unit, and more particularly, to a printed circuit board and an inspected unit simply and efficiently being inspected without being disassembled and/or damaged.

2. Description of the Related Art

Generally, a plurality of printed circuit boards are mounted to an electronic device. Recently, as environmental-oriented technologies prominently have been developed, RoHS (restriction of hazardous substances) for the electronic device, and particularly for the printed circuit boards, have become strict.

A method of manufacturing the printed circuit board comprises a soldering process to mount a circuit element on a substrate. In a solder part formed by the soldering process, hazardous substances such as lead may remain, and the hazardous substances remain on the circuit element whether the electronic device mounted with the printed circuit board is hazardous or not. Thus, to inspect whether electronic device is hazardous or not, the amount of hazardous substances that remain in the solder part is inspected. To this end, the solder part of the printed circuit board is typically inspected by an XRF (x-ray fluorescence spectrometer).

FIG. 1 is a diagram illustrating a conventional printed circuit board 10 in a surface mount state. Referring to FIG. 1, the printed circuit board 10 includes a circuit element 14 mounted on a substrate 12 by an SMT (surface mount technology). The circuit element 14 is stably supported on the substrate 12 by a solder part 16.

FIG. 2 is a diagram illustrating a conventional printed circuit board 20 in an insert mount state. Referring to FIG. 2, the printed circuit board 20 includes a circuit element 24 mounted on a substrate 22 by an IMT (insert mount technology). The circuit element 24 is stably supported on the substrate 22 by a solder part 26.

Referring to FIGS. 1 and 2, in the conventional printed circuit boards 10 and 20, it is not easy for an inspecting apparatus X to inspect the solder parts 16 and 26. Since inspection surfaces 16a and 26a of the solder parts 16 and 26 to be inspected by the inspecting apparatus X are formed to tilt with respect to a light scanning direction L of the inspecting apparatus X, diffused reflection of light may occur. Since the inspection surfaces 16a and 26a of the solder parts 16 and 26 are narrow in width, the inspecting apparatus X may not be able to scan sufficient light on the solder parts 16 and 26. Accordingly, the inspecting apparatus X may not inspect the solder parts 16 and 26 properly.

Also, in the case that it is difficult for the inspecting apparatus X to approach the printed circuit boards 10 and 20, the printed circuit boards 10 and 20 may have to be disassembled or separated from the electronic device, and accordingly, the electronic device may be damaged.

### SUMMARY OF THE INVENTION

Accordingly, it is an aspect of the present invention to provide a printed circuit board and an inspected unit efficiently being inspected without being disassembled and damaged.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept may be achieved by providing a printed circuit board comprising a substrate and an inspection piece part having a solder part provided on a surface of the substrate to be inspected by an inspecting apparatus.

The inspection piece part may be separable from the substrate.

The inspection piece part may comprise a cutting supporting part to support the solder part to the substrate to be cut off by a predetermined external force.

The cutting supporting part may be formed around a part of a circumference of the solder part.

The cutting supporting part may comprise cutting holes arranged along a circumferential portion of the solder part at a predetermined interval.

The inspection piece part may be detachably attached to a surface of the substrate.

The solder part may have a width of 3-30 mm in a surface direction of the substrate.

The solder part may have an inspection surface to be inspected by the inspecting apparatus that is flat.

The substrate and the inspection piece part may be integrally formed.

The inspecting apparatus may comprise an XRF (X-ray fluorescence spectrometer).

The foregoing and/or other aspects and utilities of the present general inventive concept may also be achieved by providing an inspected unit inspected by an inspecting apparatus, comprising a unit main body, an inspection piece part formed of the same material as the unit main body and being inspected by the inspecting apparatus, and a cutting supporting part supporting the inspection piece part to the unit main body to be cut by a predetermined external force.

The unit main body may comprise a plastic substrate.

The unit main body, the inspection piece part and the cutting supporting part may be integrally formed.

The cutting supporting part may comprise cutting holes arranged along a circumferential portion of the inspection piece part.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1 is a diagram illustrating a conventional printed circuit board in a surface mount state;

FIG. 2 is a diagram illustrating a conventional printed circuit board in an insert mount state;

FIG. 3 is a diagram illustrating a printed circuit board according to an embodiment of the present general inventive concept; and

FIG. 4 is a diagram illustrating an inspected unit according to an embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

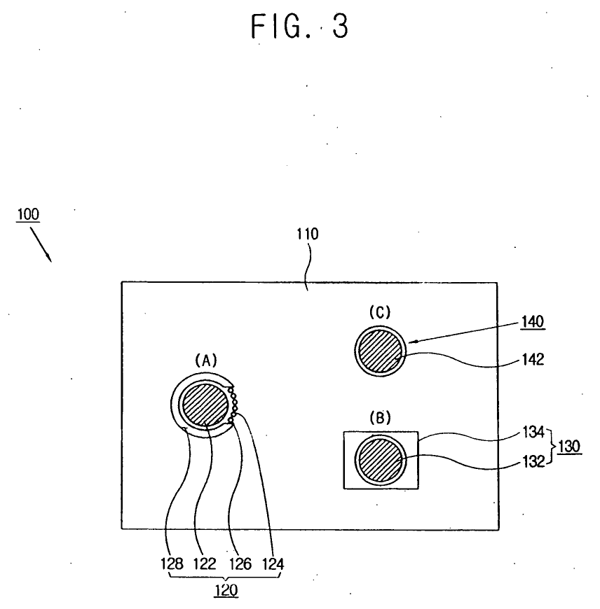

FIG. 3 is a diagram illustrating a printed circuit board 100 according to an embodiment of the present general inventive concept. Referring to FIG. 3, portions (A), (B) and (C) are three examples in which a substrate 110 is mounted with three inspection piece parts 120, 130 and 140 having different configurations.

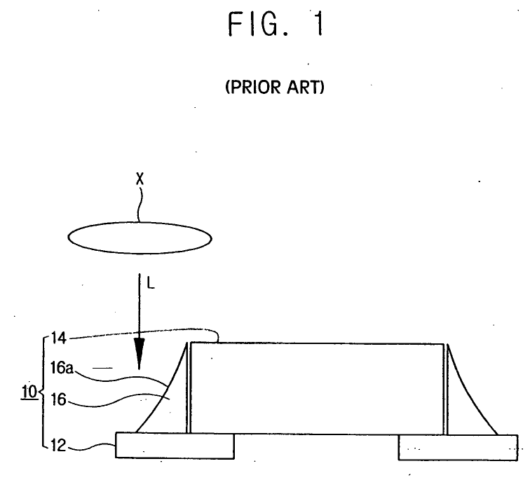

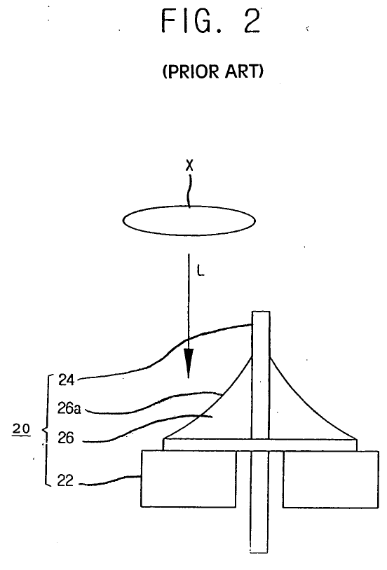

Referring to the portion (A) of FIG. 3, the printed circuit board 100 includes the substrate 110 and the inspection piece part 120. The inspection piece part 120 includes a solder part 122 provided on a surface of the substrate 110 to be inspected by an inspecting apparatus (not shown) which may be an inspecting apparatus X of FIGS. 1 and 2.

The inspecting apparatus measures ingredients of the solder part 122, and inspects the amount of hazardous substances contained in the solder part 122 such as six major hazardous substances (lead, mercury, cadmium, chrome +6, and two kinds of bromic flame retardants) or other hazardous substances. The inspecting apparatus may be an XRF (X-ray fluorescence spectrometer). The XRF scans X-ray to the solder part 122 and detects light emitted through a movement of an electron, and then inspects the ingredients of the solder part 122. Alternatively, other known inspecting apparatuses may be used. The inspecting apparatus may perform a nondestructive inspection.

The solder part 122 may have a width of 3-30 mm in a surface direction of the substrate 110. An inspection surface of the solder part 122 to be inspected by the inspecting apparatus may be flat. That is, the inspection surface of the solder part 122 may be formed in parallel with the surface of the substrate 110. Thus, the inspecting apparatus can inspect the solder part 122 precisely. The solder part 122 may be formed in a circular shape in the illustrated, for example, but the solder part 122 may be formed in a polygonal shape, such as a rectangular shape, etc., or in other shapes as long as the solder part 122 has a width of 3-30 mm in a surface direction of the substrate 110.

The inspection piece part 120 may be separated from the substrate 110. The inspection piece part 120 includes a cutting supporting part 124 to support the solder part 122 with respect to the substrate 110 to be removable from the substrate by a predetermined external force. The cutting supporting part 124 is formed around a first part of a circumference of the solder part 122, and includes a plurality of cutting holes 126 arranged at a predetermined interval. A separating part 128 is formed around a second part of the circumference portion of the solder part 122. The solder part 122 is separated from the substrate 110 by the separating part 128 since the separating part 128 is an opening formed about the second part of the circumference of the solder part 122. When the predetermined external force is applied to the inspection piece part 120 in a vertical direction with respect to the surface of the substrate 110 or a direction having an angle with the surface of the substrate 110, the cutting supporting part 124 is cut off by means of the cutting holes 126. Accordingly, the inspection piece part 120 may be separated from the substrate 110 without difficulty. For example, the cutting holes 126 may be formed in a circular shape, but alternatively, the cutting holes 126 may be formed in a slit shape extending around the first part of the circumference of the solder part 122 or in other shapes.

With the removable configuration, when an electronic device mounted with the printed circuit board is inspected, the electronic device can be inspected simply and efficiently by separating the inspection piece part 120 from the substrate 110. The printed circuit board needs to be neither disassembled nor detached, and thus the electronic device is prevented from being damaged.

The substrate 110 and the inspection piece part 120 are formed integrally. In manufacturing the substrate 110, on a portion of the substrate 110 in which the inspection piece part 120 is provided, the solder part 122 is formed by soldering without spreading a resist. Thus, the ingredients of the solder part 122 may be the same as that of a soldering portion of a circuit element (not shown) mounted on the substrate 110. Alternatively, the inspection piece part 120 may be manufactured separately from the substrate 110 and then attached to the substrate 110.

Referring to the portion (A) of FIG. 3, the inspection piece part 120 is surrounded by the substrate 110, but alternatively, the inspection piece part 120 may be provided in an edge portion of the substrate 110 so that a part of a circumference of the inspection piece part 120 is not surrounded with the substrate 110. Also, the cutting supporting part 124 of the inspection piece part 120 may be formed around the other part of the circumference of the solder part 122. In another example, the cutting supporting part 124 may be formed to surround the solder part 122. The cutting supporting part 124 of the inspection piece part 120 may have the cutting holes 126 to be cut off. In another example, instead of having the cutting holes 126, a thickness of the cutting supporting part 124 may be thinner than that of the substrate 110 to be cut off without difficulty.

Referring to the portion (B) of FIG. 3, the inspection piece part 130 is detachably attached to a surface of the substrate 110. The inspection piece part 130 may include a solder part 132, and an attaching part 134 to support the solder part 132 and being detachably attached to the substrate 110. In inspecting the electronic device, the inspection piece part 130 may be separated from the substrate 110 without difficulty by detaching the attaching part 134 from the substrate 110.

Referring to the portion (C) of FIG. 3, the inspection piece part 140 is formed on the surface of the substrate 110 to be exposed. The inspection piece part 140 is not to be separated from the substrate 110 for inspection. The inspection piece part 140 may be disposed in a position which the inspecting apparatus may approach directly. In inspecting the electronic device, without separating the printed circuit board 100 from the electronic device, the inspecting apparatus can directly approach a solder part 142 to inspect the solder part 142, and can thereby inspect the electronic device.

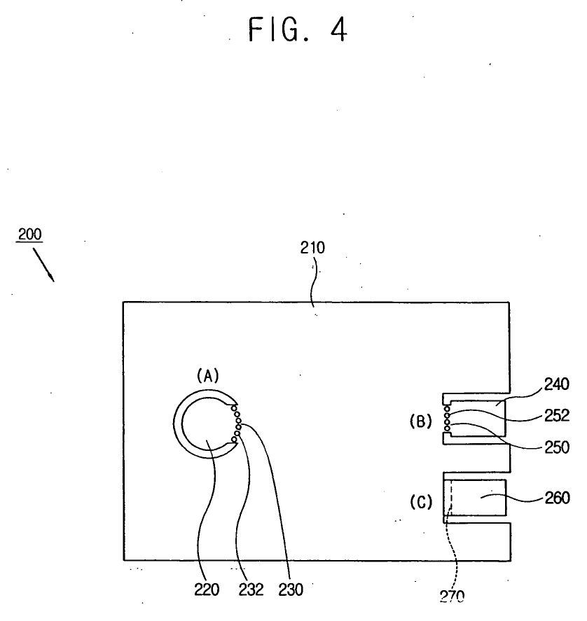

FIG. 4 is a diagram illustrating an inspected unit 200 according to an embodiment of the present general inventive concept. Portions (A), (B) and (C) in FIG. 4 illustrate three examples in which a unit main body 210 is provided with three inspection piece parts 220, 240 and 260 each having a different configuration.

Referring to the portion (A) of FIG. 4, the inspected unit 200 includes the unit main body 210, the inspection piece part 220, and a cutting supporting part 230. The inspection piece part 220 may be formed of the same material as the unit main body 210 and is inspected by an inspecting apparatus (not shown). The inspection piece part 220 may be surrounded with the unit main body 210. The cutting supporting part 230 supports the inspection piece part 220 on the unit main body 210 to be cut off by the predetermined external force. The cutting supporting part 230 may include a plurality of cutting holes 232 arranged around a part of the circumference of the inspection piece part 220.

The unit main body 210 may be a plastic substrate, and the inspection piece part 220 may be formed of the same material as the unit main body 210. The inspection piece part 220 may be formed integrally with the unit main body 210. By separating the inspection piece part 220 from the unit main body 210, the inspection piece part 220 can be inspected by the inspecting apparatus, and thus, the inspected unit 200 can be inspected without difficulty. The unit main body 210 may be a main body of a known apparatus, article or manufacture instead of the plastic substrate.

Referring to the portion (B) of FIG. 4, the inspection piece part 240 is provided in an edge portion of the unit main body 210. A cutting supporting part 250 includes cutting holes 252 formed in a side of the inspection piece part 240 to allow the cutting supporting part 250 to be cut off without difficulty. The cutting hole 252 may be formed in a circular shape or a slit shape.

Referring to the portion (C) of FIG. 4, the inspection piece part 260 is detachably supported by the unit main body 210 by a cutting supporting part 270. A thickness of the cutting supporting part 270 is thinner than that of the unit main body 210 to be cut off by the predetermined force.

The printed circuit board and the inspected unit according to the present general inventive concept allow only the inspection piece part to be inspected without disassembling and damaging the substrate and unit main body, and thereby being inspected simply and efficiently.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A printed circuit board, comprising:
a substrate; and
an inspection piece part having a solder part provided on a surface of the substrate to be inspected by an external inspecting apparatus.

2. The printed circuit board according to claim 1, wherein the inspection piece part is separable from the substrate.

3. The printed circuit board according to claim 2, wherein the inspection piece part comprises:
a cutting supporting part to support the solder part to the substrate to be cut off by a predetermined external force.

4. The printed circuit board according to claim 3, wherein the cutting supporting part is formed around a part of a circumference of the solder part.

5. The printed circuit board according to claim 3, wherein the cutting supporting part comprises cutting holes arranged along a circumferential portion of the solder part at a predetermined interval.

6. The printed circuit board according to claim 2, wherein the inspection piece part is detachably attached to the surface of the substrate.

7. The printed circuit board according to claim 1, wherein the solder part has a width of 3-30 mm in a surface direction of the substrate.

8. The printed circuit board according to claim 7, wherein an inspection surface of the solder part to be inspected by the external inspecting apparatus is flat.

9. The printed circuit board according to claim 1, wherein the substrate and the external inspection piece part are integrally formed.

10. The printed circuit board according to claim 1, wherein the external inspecting apparatus comprises an X-ray fluorescence spectrometer.

11. An inspected unit inspected by an inspecting apparatus, comprising:
a unit main body;
an inspection piece part formed of the same material as the unit main body and being inspected by the inspecting apparatus; and
a cutting supporting part to support the inspection piece part to the unit main body to be cut by a predetermined external force.

12. The inspected unit according to claim 11, wherein the unit main body comprises a plastic substrate.

13. The inspected unit according to claim 11, wherein the unit main body, the inspection piece part and the cutting supporting part are integrally formed.

14. The inspected unit according to claim 11, wherein the cutting supporting part comprises cutting holes arranged along a circumferential portion of the inspection piece part.
